(19) United States
(12) Patent Application Publication
(10) Pub. No.: US 2025/0230175 A1
(43) Pub. Date: Jul. 17, 2025

(54) SILANOLS AND SILANEDIOLS

(71) Applicant: VERSUM MATERIALS US, LLC, TEMPE, AZ (US)

(72) Inventors: DANIEL MOSER, Ph.D., MANITOWOC, WI (US); XINJIAN LEI, VISTA, CA (US)

(21) Appl. No.: 18/703,240

(22) PCT Filed: Oct. 18, 2022
(86) PCT No.: PCT/US2022/078325

§ 371 Date: Apr. 19, 2024

Related U.S. Application Data
(60) Provisional application No. 63/270,379, filed on Oct. 21, 2021.

(51) Int. Cl. C07F 7/18; C23C 16/36; C23C 16/40; C23C 16/50

(52) U.S. Cl. CPC C07F 7/1804; C23C 16/36; C23C 16/401; C23C 16/50

(57) ABSTRACT

A composition useful in depositing low dielectric constant (low k) insulating materials into high aspect ratio gaps, trenches, vias, and other surface features, of semiconductor devices by Atomic Layer Deposition (ALD) or Chemical Vapor Deposition (CVD) processes is disclosed. A first composition may comprise an alkoxysilanediol. The alkoxy-based substituent of the silanediol may be a branched, or cyclic, alkyl group having between 3 to 10 carbon atoms. In another instance, the composition may comprise an alkoxysilanol. The alkoxy-based substituent of the silanol may be a branched, or cyclic, alkyl group having between 3 to 10 carbon atoms.

### CROSS-REFERENCE TO RELATED APPLICATIONS

This application claims priority to US Provisional Patent Application having Ser. No. 63/270,379, filed on Oct. 21, 2021.

### TECHNICAL FIELD

This disclosure generally relates to silanols, and silanediols, and more particularly to alkoxysilanols, and alkoxysilanediols.

### BACKGROUND

Semiconductor device geometries continue to decrease in size, and as such, the surface density of these devices continues to increase on patterned substrates. With this increased density, the chance of electrical interference, including cross-talk and parasitic capacitance, between adjacent devices on such patterned substrates continues to increase. To reduce the likelihood of this electrical interference, low dielectric constant (low k) insulating materials are often placed in the gaps, trenches, vias, and other surface features, between adjacent devices on such patterned substrates.

Silanols, and silanediols, have attracted interest as materials to be used in the gaps, trenches, vias, and other surface features, between adjacent devices on patterned substrates. However, silanols, and silanediols, are not without issue. Some silanols, and silanediols, undergo a self-condensation reaction wherein silanol, or silanediol, molecules interact to form siloxanes, or polysiloxanes, derived from the parent molecule. For example, a first silanol molecule may undergo a condensation reaction with a second silanol molecule to form a first siloxane. Subsequently, the first siloxane may interact with a third silanol molecule, or a second siloxane, in another condensation reaction to form a polysiloxane. For better, or worse, such siloxanes, and polysiloxanes, may not be as easily vaporized and thus as easily delivered to the deposition chamber of an Atomic Layer Deposition (ALD) or Chemical Vapor Deposition (CVD) tool in comparison the parent molecule. Accordingly, a need exists for silanol, and silanediol, precursor materials that exhibit less tendency to form siloxanes, or polysiloxanes.

The present disclosure is directed to overcoming on or more problems set forth above, and/or other problems associated with the prior art.

### SUMMARY OF THE INVENTION

In accordance with one aspect of the present disclosure, an alkoxysilanediol composition useful in ALD and CVD processes is disclosed. More particularly, the composition may comprise a compound represented by the formula

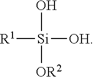

In each of the silane-diol compounds represented above, R¹ is a branched, or cyclic, alkyl group having 3 to 10 carbon atoms. In each of the compounds represented above, R² is a branched, or cyclic, alkyl group having 3 to 10 carbon atoms.

In accordance with a preferred embodiment of this aspect of the invention, the alkoxysilanediol may be selected from the group consisting of:

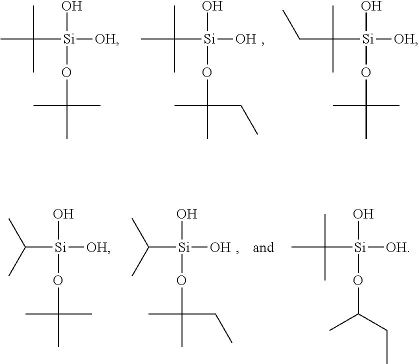

In accordance with an additional aspect of this invention, an alkoxysilanol composition useful in ALD and CVD processes is disclosed. The alkoxysilanol disclosed herein may be depicted by the formula

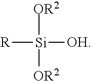

In each of the compounds represented above, R is a linear alkyl having 2 to 6 carbon atoms, a branched or cyclic alkyl having 3 to 6 carbon atoms, or an aryl having 6 to 12 carbon atoms. In each of the compounds represented above, R² is a branched, or cyclic, alkyl group having 3 to 10 carbon atoms.

In a preferred embodiment of this aspect of the invention, the alkoxysilanol may be selected from the group consisting of:

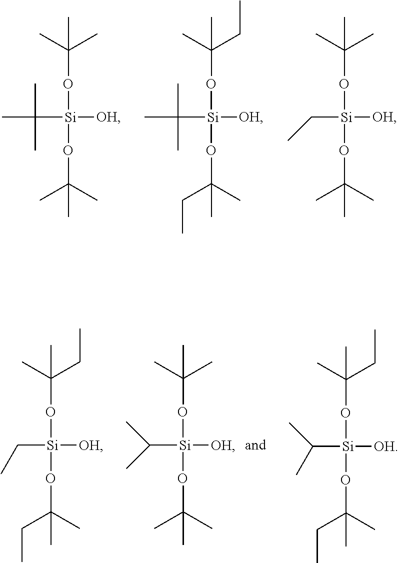

In accordance with a third aspect of the invention disclosed herein, a method of forming a silicon-containing film is disclosed. This method may include the step of positioning a substrate inside a deposition chamber of an ALD or CVD tool. The deposition chamber of the ALD or CVD tool may be injected with a silicon and oxygen containing compound and a co-reactant. The silicon and oxygen containing compound and the co-reactant may be exposed to an in-situ generated plasma when in the deposition chamber thereby forming a silicon-and-oxygen-containing-compound-co-reactant-reaction-product. Another step may comprise allowing the silicon-and-oxygen-containing-compound-co-reactant-reaction-product to deposit on the substrate thereby forming the silicon-containing film.

The substrate in this method may be patterned or non-patterned, and the silicon and oxygen containing compound may be an alkoxysilanediol compound depicted by the formula

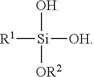

In this instance R¹ is a branched, or cyclic, alkyl group having 3 to 10 carbon atoms, and wherein R² is a branched, or cyclic, alkyl group having 3 to 10 carbon atoms. In preferred embodiments of this method, the alkoxysilanediol may be selected from the group consisting of:

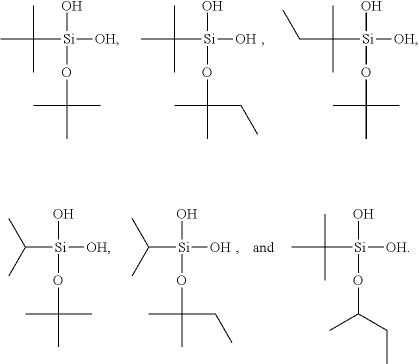

In another instance of this method, silicon and oxygen containing compound may be an alkoxysilanol depicted by the formula

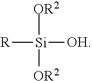

In this instance, R is a linear alkyl having 2 to 6 carbon atoms, a branched or cyclic alkyl group having 3 to 6 carbon atoms, or an aryl having 6 to 12 carbon atoms, and R² is a branched, or cyclic, alkyl group having 3 to 10 carbon atoms. In preferred embodiments of this method, the alkoxysilanol may be selected from the group consisting of:

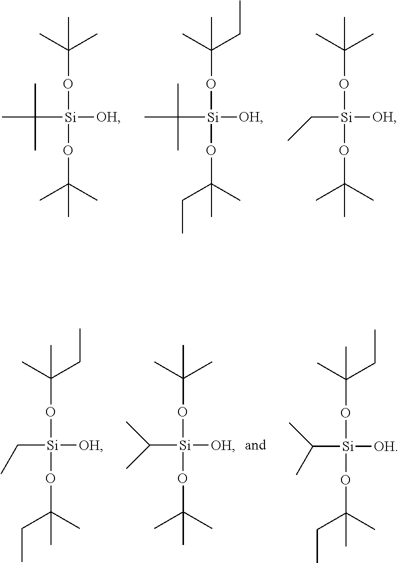

Finally, the co-reactant utilized in this method may be selected from the group consisting of nitrogen (N₂), ammonia (NH₃), oxygen (O₂), ozone (O₃) and water (H₂O).

### BRIEF DESCRIPTION OF THE DRAWINGS

FIG. 1 is a Thermogravimetric Analysis (TGA) of the compound tert-butyl-tertbutoxysilanediol manufactured in accordance with the present disclosure.

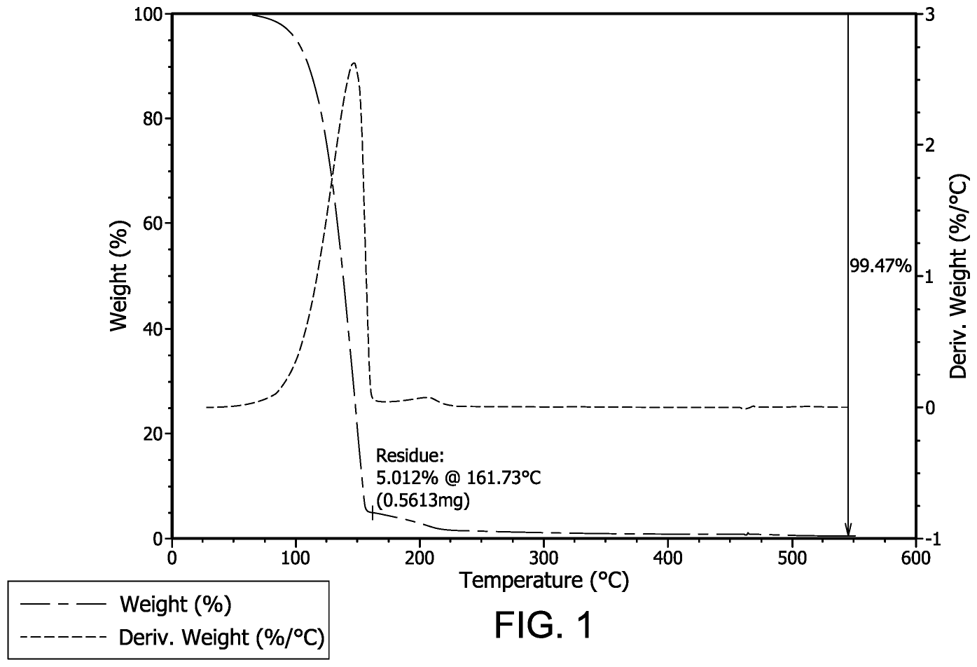

FIG. 2 is a TGA of the compound tert-butyl-tertpentoxysilanediol manufactured in accordance with the present disclosure.

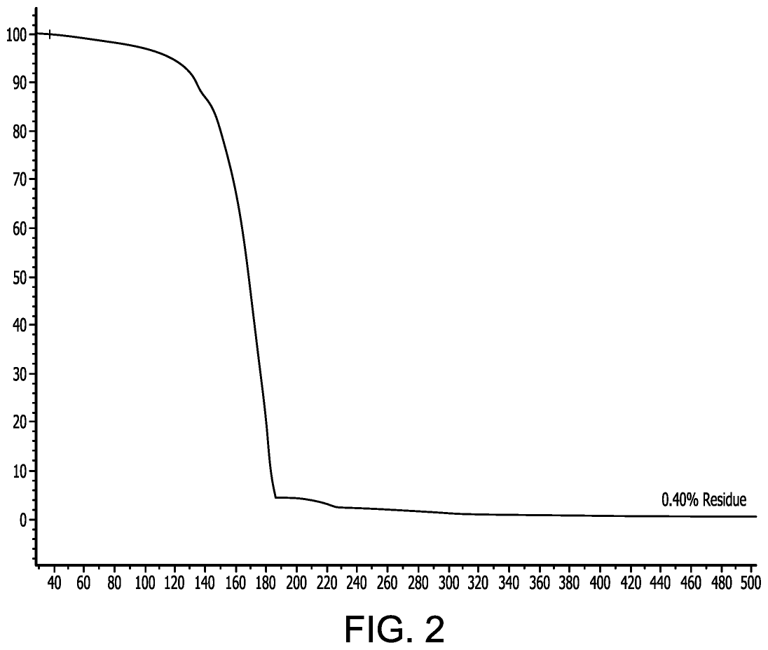

### DETAILED DESCRIPTION

Various aspects of the disclosure will now be described with reference to the drawings and tables disclosed herein, if applicable, with like reference numbers referring to like elements, unless specified otherwise. As described above, some silanols, and silanediols, undergo a self-condensation reaction wherein silanol, or silanediol, molecules interact to form siloxanes, or polysiloxanes, derived from the parent molecule. Such siloxanes, and polysiloxanes, may not be as easily vaporized and thus as easily delivered to the deposition chamber of an ALD or CVD tool in comparison the parent molecule. As such, the Applicant researched means to reduce the likelihood that silanols, and silanediols, applicable to the thin-film art area form siloxanes, or polysiloxanes, before being able to be delivered to the deposition chamber of the ALD or CVD tool.

With the above in mind, the Applicant understands that a first silanol molecule may undergo a condensation reaction with a second silanol molecule to form a first siloxane. The Applicant also understands that such first siloxane may interact with a third silanol molecule, or a second siloxane, in a condensation reaction to subsequently form a polysiloxane. In addition, the Applicant understands that an analogous reaction pathway occurs with silanediol chemistry. As such, the Applicant theorized that substituting silanols, and silanediols, with sterically hindering substituents such as branched or cyclic alkyl groups inhibits the condensation reaction pathway, thereby lessening the formation of siloxanes and polysiloxanes derived from the parent material.

To this end, the Applicant synthesized tert-butyl-tertbutoxysilanediol, and conducted a stability study of the resulting material. More specifically, and as described in more detail below, the Applicant exposed the synthesized tert-butyl-tertbutoxysilanediol material to an elevated temperature of 110° C. for four weeks. The Applicant then took a sample of the material exposed to the elevated temperature for four weeks and analyzed it by Nuclear Magnetic Resonance (NMR). Per the NMR spectrum, no decomposition of the material was observed, including no formation of siloxanes, or polysiloxanes.

Accordingly, disclosed herein in a first aspect of the invention, are novel, and non-obvious, compositions comprising alkoxysilanediol compounds useful as a precursor in ALD and CVD processes. The compounds disclosed herein include those depicted by the formula below:

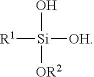

In each of the compounds represented above, R¹ is a branched, or cyclic, alkyl group having 3 to 10 carbon atoms. In each of the compounds represented above, R² is a branched, or cyclic, alkyl group having 3 to 10 carbon atoms.

In a more preferred embodiment of this first aspect of the invention, a composition is disclosed wherein the alkoxysilanediol is selected from the group consisting of:

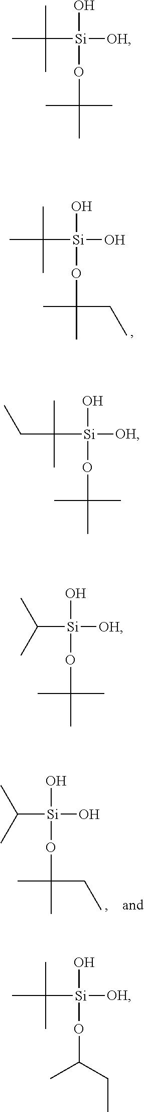

### Synthesis of Alkoxysilanediols

### Working Example 1—General Synthesis of Alkoxysilanediols

Both one equivalent of alkyltrichlorosilane, R¹SiCl₃ and one equivalent alkali alkoxide are dissolved in tetrahydrofuran. The alkali alkoxide solution is added to the stirring flask of the alkyltrichlorosilane, slowly at room temperature. The reaction is exothermic slightly above room temperature. The reaction mixture is cooled and was quenched using 1 equivalent of pyridine dissolved in excess water. This results in formation of the diol. The mixture was transferred to a separatory funnel and the layers were separated and the organic layer was extracted with water to remove any residual salts. The organic layer was dried over MgSO₄ and filtered. The solvent was removed in vacuo resulting alkoxysilanediol product. The compounds were dissolved in solvent to run GC and NMR.
A general synthesis for Alkoxysilanediols is depicted below:

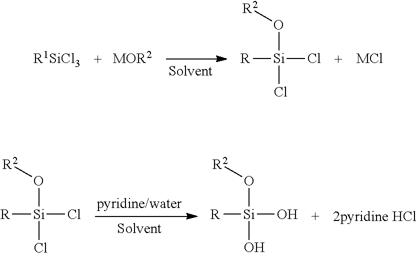

In each of the compounds represented above, R¹ is a branched, or cyclic, alkyl group having 3 to 10 carbon atoms. In each of the compounds represented above, R² is a branched, or cyclic, alkyl group having 3 to 10 carbon atoms. Finally, M=Li, Na or K.

### Working Example 2—Synthesis of Tert-Butyl-Tertbutoxysilanediol

Tert-butyltrichlorosilane, 18.7 g (0.1 moles), was dissolved in 100 mL of THF and potassium t-butoxide, 11 g (0.1 moles) was dissolved in 50 mL of THF. The potassium t-butoxide was added to the stirring flask of the tert-butyltrichlorosilane, slowly at room temperature. The reaction is exothermic and raised the temperature 40° C. Once cooled, the reaction was quenched using pyridine, 15 g (0.2 mole), mixed with 80 g of water. This results in formation of the diol. The mixture was transferred to a separatory funnel and the layers were separated and the organic layer was extracted with water to remove any residual salts. The organic layer was dried over MgSO₄ and filtered. The solvent was removed in vacuo resulting in 16 g (75%) of white solid. The solids were dissolved in solvent to run GC and NMR. Material was 99% by GC and GCMS confirmed product. TGA included in this application, 0.5% residue. M.p. of C₈H₂₀O₃Si is 149-152° C. ¹H NMR (500 MHz, 298 K, C₆D₆) δ: 2.13 (s, 2H, OH), 1.28 (s, 9H, OC(CH₃)₃), 1.08 (s, 9H, C(CH₃)₃). MS, m/z 192.0 (M⁺), 177.1 (M⁺-CH₃).

### Working Example 3—Stability Testing of Tert-Butyl-Tertbutoxysilanediol

5 g of tert-butyl-tertbutoxysilanediol was put into a stainless-steel ampoule and heated to 110° C. After 4 weeks of heating, the material was run on NMR and compared to the initial material. No decomposition observed by NMR. Material is stable at elevated temperatures.

### Working Example 4—Synthesis of Tert-Butyl-Tertpentoxysilanediol

Tert-butyltrichlorosilane, 80 g (0.41 moles), was dissolved in 300 mL of THF and sodium t-pentoxide, 51 g (0.44 moles) was dissolved in 300 mL of THF. The sodium t-pentoxide was added to the stirring flask of the tert-butyltrichlorosilane, slowly at room temperature. The reaction is exothermic and raised the temperature 40° C. Once cooled, the reaction was quenched using pyridine, 82 g (1.0 mole), mixed with 400 g of water. This results in formation of the diol. The mixture was transferred to a separatory funnel and the layers were separated and the organic layer was extracted with water to remove any residual salts. The organic layer was dried over MgSO₄ and filtered. The solvent was removed in vacuo resulting in 77 g (88%) of white solid. The solids were dissolved in solvent to run GC and NMR. Material was 99% by GC and GCMS confirmed product. M.p. of C₉H₂₂O₃Si is 128-131° C. TGA included in this application. 0.4% residue after heating. ¹H NMR (500 MHz, 298 K, C6D6) δ: 3.38 (s, 2H, OH), 1.54 (q, 2H, CH₂CH₃), 1.31 (s, 6H, C(CH₃)₂), 1.13 (s, 9H, C(CH₃)₃), 0.95 (t, 3H, CH₂CH₃). MS, m/z 206.0 (M⁺), 191 (M⁺-CH₃).

In a second aspect of this invention, novel, and non-obvious, compositions comprising alkoxysilanol compounds useful as a precursor in ALD and CVD processes are disclosed. The compounds disclosed herein include those depicted by the formula below:

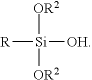

In each of the compounds represented above, R is a linear alkyl having 2 to 6 carbon atoms, a branched or cyclic alkyl group having 3 to 6 carbon atoms, or an aryl having 6 to 12 carbon atoms. In each of the compounds represented above, R² is a branched, or cyclic, alkyl group having 3 to 10 carbon atoms.

In a more preferred embodiment of this second aspect of the invention, a composition is disclosed wherein the alkoxysilanol is selected from the group consisting of:

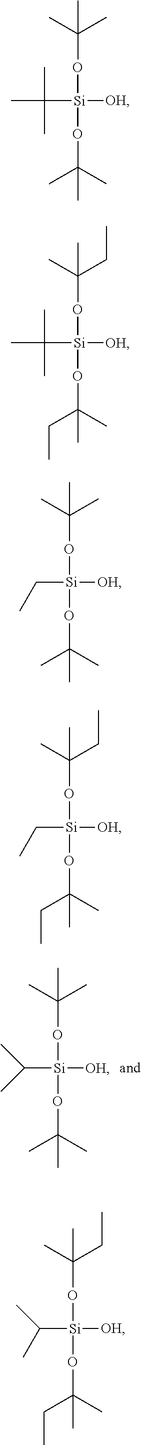

### Synthesis of Alkoxysilanols

### Working Example 5—General Synthesis of RSi(OR²)₂OH Alkoxysilanols

For alkyl substituted Alkoxysilanols, both one equivalent of alkyltrichlorosilane, RSiCl₃ and 2 equivalent alkali alkoxide are dissolved in tetrahydrofuran. The alkali alkoxide solution is added to the stirring flask of the alkyltrichlorosilane, slowly at room temperature. The reaction is exothermic slightly above room temperature. The reaction mixture is cooled and was quenched using 2 equivalents of pyridine dissolved in excess water. This results in formation of the silanol. The mixture was transferred to a separatory funnel and the layers were separated and the organic layer was extracted with water to remove any residual salts. The organic layer was dried over MgSO₄ and filtered. The solvent was removed in vacuo resulting alkylbis(alkoxy)silanol product. The compounds were dissolved in solvent to run GC and NMR.
For aryl substituted Alkoxysilanols, both one equivalent of aryltrichlorosilane, RSiCl₃ and 2 equivalent alkali alkoxide are dissolved in tetrahydrofuran. The alkali alkoxide solution is added to the stirring flask of the aryltrichlorosilane, slowly at room temperature. The reaction is exothermic slightly above room temperature. The reaction mixture is cooled and was quenched using 2 equivalents of pyridine dissolved in excess water. This results in formation of the silanol. The mixture was transferred to a separatory funnel and the layers were separated and the organic layer was extracted with water to remove any residual salts. The organic layer was dried over MgSO₄ and filtered. The solvent was removed in vacuo resulting arylbis(alkoxy)silanol product. The compounds were dissolved in solvent to run GC and NMR.
A general synthesis for Alkoxysilanols is depicted below:

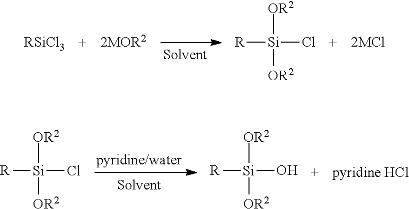

In each of the compounds represented above, R is a linear alkyl having 2 to 6 carbon atoms, a branched or cyclic alkyl having 3 to 6 carbon atoms, or an aryl group having 6 to 12 carbon atoms. In each of the compounds represented above, R² is a branched, or cyclic, alkyl group having 3 to 10 carbon atoms. Finally, M=Li, Na or K.

### Working Example 6—Synthesis of T-Butyl Bis(t-Butoxy)Silanol

Tert-butyltrichlorosilane, 9.6 g (0.05 moles), was dissolved in 60 mL of THF and potassium t-butoxide, 11.25 g (0.10 moles) was dissolved in 60 mL of THF. The potassium t-butoxide was added to the stirring flask of the tert-butyltrichlorosilane, slowly at room temperature. The reaction is exothermic and raised the temperature 50° C. Once cooled, the reaction was quenched using pyridine, 4.1 g (0.05 mole), mixed with 50 g of water. This results in formation of the silanol. The mixture was transferred to a separatory funnel and the layers were separated and the organic layer was extracted with water to remove any residual salts. The organic layer was dried over MgSO₄ and filtered. The solvent was removed in vacuo resulting in 9 g (70%) of white solid. The solids were dissolved in solvent to run GC and NMR. Material was 99% by GC and NMR confirmed product. M.p. of C₁₂H₂₈O₃Si is 52-54° C. ¹H NMR (500 MHz, 298 K, C₆D₆) δ:1.61 (s, 1H, OH), 1.31 (s, 18H, OC(CH₃)₃), 1.11 (s, 9H, C(CH₃)₃).

### INDUSTRIAL APPLICABILITY

In operation, the alkoxysilanols, and alkoxysilanediols, described and depicted above find applicability in many industrial applications including, but not limited to, their use as an insulating material deposited in the gaps, trenches, vias, and other surface features, between adjacent devices on patterned substrates. Accordingly, in a third aspect of the invention disclosed herein, a method of depositing a silicon-containing film with the alkoxysilanols, and alkoxysilanediols, described and depicted above is disclosed. In a first step of this method, a substrate may be positioned inside a deposition chamber of an ALD or CVD tool. The substrate may be patterned or non-patterned. A patterned substrate may include gaps, trenches, vias, and other surface features, between adjacent devices on the substrate. A non-patterned substrate may be a silicon substrate, for example, without any gaps, trenches, vias, or other surface features.

Suitable substrate materials may include semiconductor materials such as gallium arsenide (“GaAs”), silicon, and compositions containing silicon such as crystalline silicon, polysilicon, amorphous silicon, epitaxial silicon, silicon dioxide (“SiO₂”), silicon glass, silicon nitride, fused silica, glass, quartz, borosilicate glass, and combinations thereof. Other suitable materials include chromium, molybdenum, and other metals commonly employed in semi-conductor, integrated circuits, flat panel display, and flexible display applications. The substrate may have additional layers such as, for example, silicon, SiO₂, organosilicate glass (OSG), fluorinated silicate glass (FSG), boron carbonitride, silicon carbide, hydrogenated silicon carbide, silicon nitride, hydrogenated silicon nitride, silicon carbonitride, hydrogenated silicon carbonitride, boronitride, organic-inorganic composite materials, photoresists, organic polymers, porous organic and inorganic materials and composites, metal oxides such as aluminum oxide, and germanium oxide. Still further layers can also be germanosilicates, aluminosilicates, copper and aluminum, and diffusion barrier materials such as, but not limited to, TiN, Ti(C)N, TaN, Ta(C)N, Ta, W, or WN.

In another step, the deposition chamber of the ALD or CVD tool may be injected with a silicon and oxygen containing compound and a co-reactant. The silicon and oxygen containing compound and the co-reactant may be exposed to an in-situ plasma generator when in the deposition chamber thereby forming a silicon-and-oxygen-containing-compound-co-reactant-reaction-product. Another step may comprise allowing the silicon-and-oxygen-containing-compound-co-reactant-reaction-product to deposit on the substrate thereby forming the silicon-containing film.

The substrate in this method may be patterned or non-patterned, and the silicon and oxygen containing compound may be an alkoxysilanediol compound depicted by the formula

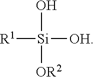

In this instance R¹ is a branched, or cyclic, alkyl group having 3 to 10 carbon atoms, and wherein R² is a branched, or cyclic, alkyl group having 3 to 10 carbon atoms. In preferred embodiments of this method, the alkoxysilanediol may be selected from the group consisting of:

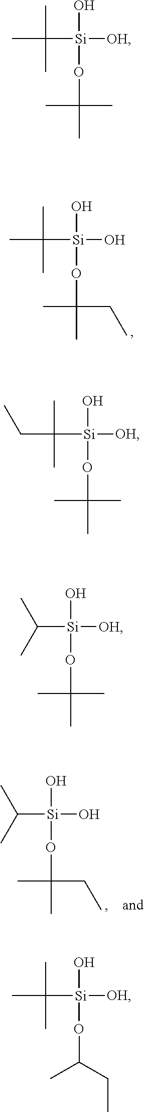

In another instance of this method, silicon and oxygen containing compound may be an alkoxysilanol depicted by the formula

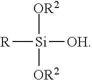

In this instance, R is a linear alkyl having 2 to 6 carbon atoms, a branched or cyclic alkyl having 3 to 6 carbon atoms, or an aryl having 6 to 12 carbon atoms, and R² is a branched, or cyclic, alkyl group having 3 to 10 carbon atoms. In preferred embodiments of this method, the alkoxysilanol may be selected from the group consisting of:

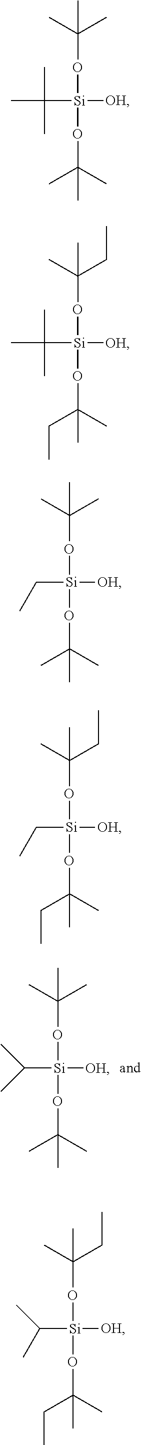

Finally, the co-reactant utilized in this method may be selected from the group consisting of nitrogen (N₂), ammonia (NH₃), oxygen (O₂), ozone (O₃) and water (H₂O).

### Formation of Silicon-Containing Films

### Working Example 7—Deposition of Silicon Carbonitride Films Using Tert-Butyl-Tertbutoxysilanediol with In Situ Plasma (Prophetic)

Flowable CVD depositions are conducted using a design of experiment (DOE) methodology. The experimental design includes: tert-butyl-tert-butoxysilanediol in a solvent is introduced into the CVD chamber with a flow rate from 100 to 5000 mg/min, preferably 1000 to 2000 mg/min; a flow rate of NH₃ from 100 sccm to 3000 sccm, preferably 500 to 1500 sccm; chamber pressure from 0.75 to 12 Torr, preferably 4 to 8 Torr; in situ plasma power 100 to 1000 W, preferably 150-300 W; and deposition temperature ranges from 0 to 550° C., preferably 0 to 150° C.
A number of SiOCN films are deposited using tert-butyl-tert-butoxysilanediol as a precursor onto 8-inch silicon substrates and patterned substrates to compare the flowability, film density, and wet etch rate.

### Working Example 8—Deposition of Silicon Oxide Films Using Tert-Butyl-Tertbutoxysilanediol with In Situ Plasma (Prophetic)

A number of silicon oxide films are deposited using tert-butyl-tert-butoxysilanediol as a precursor onto 8-inch silicon substrates and patterned substrates to compare the flowability, film density, and wet etch rate.
The most favorable deposition conditions are as follows: tert-butyl-tertbutoxysilanediol in a solvent is introduced into CVD chamber with a flow rate ranging from 100 to 5000 mg/min, preferably 1000 to 2000 mg/min, O₂ flow=1500-4500 sccm, He carrier flow=50 sccm, Pressure=0.5-2 Torr, Remote plasma power=3000 W, and temperature=10-20° C.). Wet and soft films are deposited on the blanket wafers. The as-deposited films are thermally annealed at 300° C. for 5 min and UV cured at 400° C. for 10 min. Bottom-up, seamless, and void-free gap-filling is achieved on pattern wafers by the flowable SiOC films.
In addition, the novel alkoxysilanols, and alkoxysilanediols may be used advantageously in a method for forming a metal or metalloid silicate on a substrate, such as a dielectric layer in an electronic device fabrication of solid state transistors, capacitors, vias, and circuits in general by contacting a metal or metalloid containing compound with an alkoxysilanols, and alkoxysilanediols and mixtures thereof and reacting the metal or metalloid containing compound with the alkoxysilanols or alkoxysilanediols to form the metal or metalloid silicate on the substrate. Preferably, the alkoxysilanols or alkoxysilanediols and the metal or metalloid containing compounds are each made available in the liquid state and thus delivered into the CVD/ALD chamber via direct liquid injection method. Typically, the metal or metalloid is selected from the group consisting of titanium, hafnium, zirconium, yttrium, lanthanum, scandium, magnesium, boron, aluminum, and mixtures thereof. The ligand which is used to make the metal or metalloid compound could be amides, alkyls, alkoxides, halides and mixtures thereof.

The above description is meant to be representative only, and thus modifications may be made to the embodiments described herein without departing from the scope of the disclosure. Thus, these modifications fall within the scope of the present disclosure, and are intended to fall within the appended claims.

What is claimed is:

1. An alkoxysilanediol compound depicted by the formula 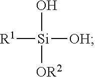
wherein R¹ is a branched or cyclic alkyl having 3 to 10 carbon atoms; and
wherein R² is a branched or cyclic alkyl having 3 to 10 carbon atoms.

2. The compound according to claim 1, wherein the compound is selected from the group consisting of:

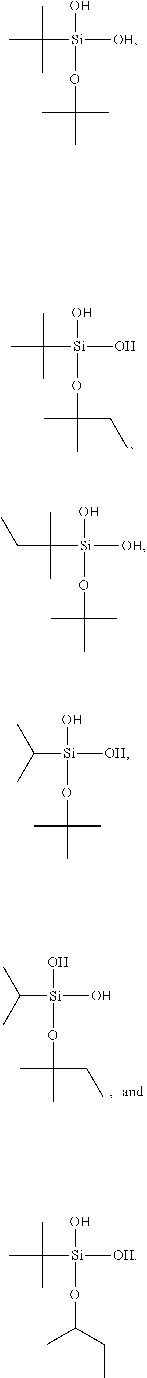

3. An alkoxysilyl compound containing a hydroxyl group depicted by the following formula 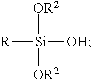
wherein R is a linear alkyl having 2 to 6 carbon atoms, a branched or cyclic alkyl having 3 to 6 carbon atoms, or an aryl having 6 to 12 carbon atoms; and
wherein R² is a branched or cyclic alkyl having 3 to 10 carbon atoms.

4. The compound according to claim 3, wherein the compound is selected from the group consisting of:

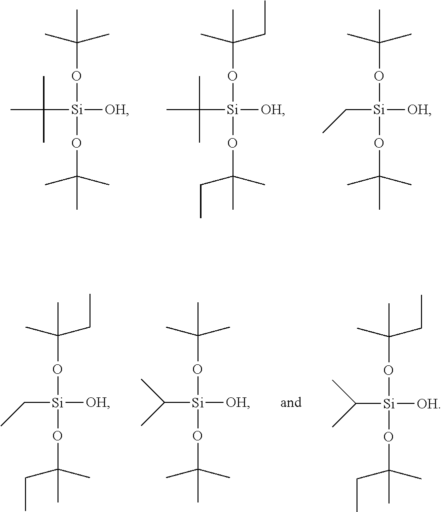 [SMILES: CC(C)(C)O[Si](O)(OC(C)(C)C)C(C)(C)C ; CCC(C)(C)O[Si](O)(OC(C)(C)CC)C(C)(C)C ; CC[Si](O)(OC(C)(C)C)OC(C)(C)C ; CCC(C)(C)O[Si](O)(CC)OC(C)(C)CC ; CC(C)[Si](O)(OC(C)(C)C)OC(C)(C)C ; CCC(C)(C)O[Si](O)(OC(C)(C)CC)C(C)C]

5. A method of forming a silicon-containing film, comprising:
positioning a substrate inside a deposition chamber of an ALD or CVD tool;
injecting the deposition chamber with a silicon and oxygen containing compound and a co-reactant, wherein the silicon and oxygen containing compound is:
an alkoxysilanediol compound depicted by the following formula: 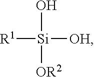
wherein R¹ is a branched or cyclic alkyl having 3 to 10 carbon atoms; and
wherein R² is a branched or cyclic alkyl having 3 to 10 carbon atoms; or
an alkoxysilanol depicted by the following formula: 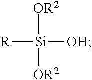
wherein R is a linear alkyl having 2 to 6 carbon atoms, a branched or cyclic alkyl having 3 to 6 carbon atoms, or an aryl having 6 to 12 carbon atoms; and
wherein R² is a branched or cyclic alkyl having 3 to 10 carbon atoms;
exposing the silicon and oxygen containing compound and the co-reactant to an in-situ generated plasma when in the deposition chamber thereby forming a silicon-and-oxygen-containing-compound-co-reactant-reaction-product; and
allowing the silicon-and-oxygen-containing-compound-co-reactant-reaction-product to deposit on the substrate thereby forming the silicon-containing film.

6. The method of forming a silicon-containing film according to claim 5, wherein the substrate is patterned or non-patterned.

7. The method of forming a silicon-containing film according to claim 5, wherein the alkoxysilanediol is selected from the group consisting of:

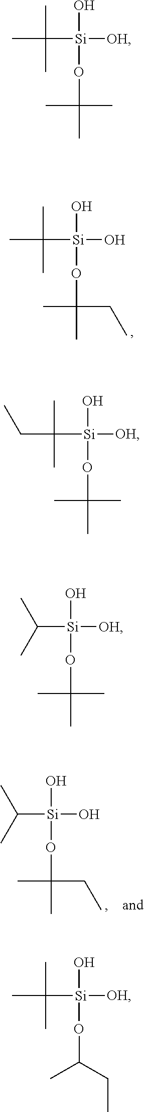

10. The method according to claim 5, wherein the alkoxysilanol is selected from the group consisting of:

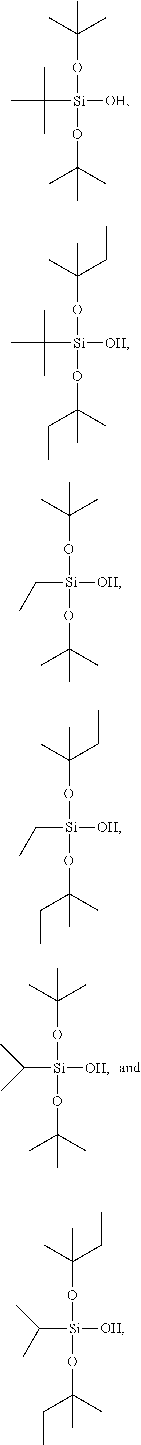

9. The method of forming a silicon-containing film according to claim 5, wherein the co-reactant is selected form the group consisting of nitrogen (N₂), ammonia (NH₃), oxygen (O₂), ozone (O₃) and water (H₂O).
